(19) United States
(12) Patent Application Publication
(10) Pub. No.: US 2013/0276983 A1
(43) Pub. Date: Oct. 24, 2013

(54) INJECTION MEMBER FOR MANUFACTURING SEMICONDUCTOR DEVICE AND PLASMA PROCESSING APPARATUS HAVING THE SAME

(71) Applicants: Yong Sung Park, Cheonan-si (KR); Sung Kwang Lee, Cheonan-si (KR); Dong Yeul Kim, Cheonan-si (KR); Kazuyuki Toyoda, Toyama (JP); Osamu Kasahara, Toyama (JP); Tetsuaki Inada, Toyama (JP)

(72) Inventors: Yong Sung Park, Cheonan-si (KR); Sung Kwang Lee, Cheonan-si (KR); Dong Yeul Kim, Cheonan-si (KR); Kazuyuki Toyoda, Toyama (JP); Osamu Kasahara, Toyama (JP); Tetsuaki Inada, Toyama (JP)

(73) Assignees: HITACHI KOKUSAI ELECTRIC INC., Tokyo (JP); KOOKJE ELECTRIC KOREA CO., LTD., Cheonan-Si, Chungcheongnam-do (KR)

(21) Appl. No.: 13/993,277

(22) PCT Filed: Jan. 12, 2012
(86) PCT No.: PCT/KR2012/000297

§ 371 Date: Jun. 11, 2013

(30) Foreign Application Priority Data
Jan. 13, 2011 (KR) 10-2011-0003681

(51) Int. Cl. H01L 21/203; H01L 21/3065

(52) U.S. Cl. CPC H01L 21/203; H01L 21/3065
USPC 156/345.34; 156/345.33; 118/723 R; 118/723 E; 239/562

(57) ABSTRACT

A plasma processing apparatus may include a process chamber configured to perform a plasma using process and contain a plurality of substrates, a support member provided in the process chamber, the substrates being laid on the same level of the support member, an injection member provided to face the support member and include a plurality of baffles, such that at least one reaction gas and a purge gas can be injected onto the substrates in an independent manner, and a driving part configured to rotate the support member or the injection member, such that the baffles of the injection member can orbit with respect to the plurality of the substrates laid on the support member. The injection member may include a plasma generator, which may be provided on at least one, configured to inject the reaction gas, of the baffles to turn the reaction gas into plasma.

### BACKGROUND OF THE INVENTION

Embodiments of the inventive concepts relate to a thin film treatment apparatus to be used for manufacturing a semiconductor device, more particularly, to an injection member with a plasma generator and a plasma processing apparatus having the injection member.

A plasma processing apparatus has been widely used for several processes, such as, a dry etching process, physical and chemical depositions, and a surface treatment process, for fabricating a semiconductor device.

A conventional plasma processing apparatus is configured to include a first electrode connected to a showerhead and a second electrode connected to a chamber. In addition, the conventional plasma processing apparatus may further include surrounding parts, such as electrical interconnection part, noise shielding part, and a part for applying a plasma bias to a susceptor.

Since conventional plasma processing apparatuses have a one-body type showerhead, it has been hard to control a space between the substrate and the showerhead.

Although conventional plasma processing apparatuses have a remote plasma generator, in the case that a plasma source is spaced far apart from a substrate, there is a technical difficulty in forming a thin film on the substrate. For example, there may be a heavy loss of ionized gas, and this leads to a delay in process time and deterioration in quality of thin film. As a result, the use of the conventional plasma processing apparatuses has been limited.

### SUMMARY

Embodiments of the inventive concepts provide an injection member, which can mount a plurality of substrates on a rotating large area support member and generate stably plasma thereon, and a plasma processing apparatus having the same.

Other embodiments of the inventive concepts provide an injection member, in which a space between a substrate and a plasma generating region can be controlled depending on a state of the substrate, and a plasma processing apparatus having the same.

According to example embodiments of inventive concepts, a plasma processing apparatus may include a process chamber configured to perform a plasma using process and contain a plurality of substrates, a support member provided in the process chamber, the substrates being laid on the same level of the support member, an injection member provided to face the support member and include a plurality of baffles, such that at least one reaction gas and a purge gas can be injected onto the substrates in an independent manner, and a driving part configured to rotate the support member or the injection member, such that the baffles of the injection member can orbit with respect to the plurality of the substrates laid on the support member. The injection member may include a plasma generator, which may be provided on at least one, configured to inject the reaction gas, of the baffles to turn the reaction gas into plasma.

In example embodiments, the injection member may further include a level controller configured to be able to control a vertical position of the plasma generator, thereby adjusting a space between the plasma generator and the substrate selectively.

In example embodiments, the injection member may be configured to have an opening for equipping the plasma generator to the at least one baffle, and the injection member may further include a bellows surrounding the plasma generator to maintain a sealed state.

In example embodiments, the plasma generator may include a body portion having a bottom surface facing the substrate, first electrodes provided on the bottom surface of the body portion and applied with a high frequency power for turning a gas into plasma, and second electrodes provided on the bottom surfaceₘof the body portion and between the first electrodes and applied with a bias power.

In example embodiments, the first electrodes and the second electrodes may be coplanar with each other and form a radial configuration, thereby allowing the substrate to be uniformly exposed by a plasma existing region during a rotation of the support member or the injection member.

In example embodiments, the first electrodes and the second electrodes may be arranged to form a comb-type configuration.

In example embodiments, the plasma generator may include a body portion having a bottom surface facing the substrate, first electrodes provided on the bottom surface of the body portion and applied with a high frequency power for turning a gas into plasma, and second electrodes provided on the bottom surface of the body portion and between the first electrodes and applied with a bias power. The first electrodes and the second electrodes may be arranged at the same level to form coil-like configurations.

In example embodiments, the injection member may include an upper plate shaped like a circular disk, and partitions provided on a bottom surface of the upper plate to delimit the baffles.

In example embodiments, the injection member may further include a nozzle part provided at a center of the upper plate and configured to inject each of the at least one reaction gas and the purge gas into the corresponding one of the baffles.

In example embodiments, the injection member may further include a showerhead plate provided to face the support member, and the showerhead plate may be equipped below the baffle provided with the plasma generator and may be spaced apart from the plasma generator.

According to example embodiments of inventive concepts, an injection member for a plasma processing apparatus may include an upper plate shaped like a circular disk, and a nozzle part provided at a center of the upper plate to have at least four injection openings, each of which may be configured to inject the corresponding one of reaction and purge gases in an independent manner, at least four baffles provided on the upper plate to form a radial configuration around the nozzle part, each of the at least four baffles being connected to the corresponding one of the at least four injection openings to contain the corresponding one of the gases separately, and a plasma generator provided on one of the at least four baffles to turn the reaction gas into plasma.

### BRIEF DESCRIPTION OF THE DRAWINGS

Example embodiments will be more clearly understood from the following brief description taken in conjunction with the accompanying drawings. The accompanying drawings represent non-limiting, example embodiments as described herein.

FIG. 1 is a schematic diagram of a deposition apparatus according to example embodiments of inventive concepts;

FIGS. 2A and 2B are perspective and sectional views of the injection member of FIG. 1;

FIG. 3 is a plan view of the support member of FIG. 1;

FIG. 4A is a sectional view enlarging the plasma generator of the injection member, and FIG. 4B is a sectional view illustrating a configuration, in which the plasma generator of FIG. 4A is lowered by a level controller;

FIG. 5 is a sectional view illustrating a modified example of an injection member, in which a showerhead plate is mounted on a third baffle;

FIG. 6 is a sectional view illustrating an injection member provided with a showerhead-type plasma generator;

FIG. 7 is a sectional view illustrating an example of an injection member, in which first and second electrodes are equipped on a bottom surface of a plasma generator;

FIG. 8 is a diagram illustrating modified examples of first and second electrodes in the plasma generator; and

FIG. 9 is a diagram exemplarily illustrating a plasma generator in an injection member modified from that of FIG. 2B.

It should be noted that these figures are intended to illustrate the general characteristics of methods, structure and/or materials utilized in certain example embodiments and to supplement the written description provided below. These drawings are not, however, to scale and may not precisely reflect the precise structural or performance characteristics of any given embodiment, and should not be interpreted as defining or limiting the range of values or properties encompassed by example embodiments. For example, the relative thicknesses and positioning of molecules, layers, regions and/or structural elements may be reduced or exaggerated for clarity. The use of similar or identical reference numbers in the various drawings is intended to indicate the presence of a similar or identical element or feature.

### DETAILED DESCRIPTION

Example embodiments of the inventive concepts will now be described more fully with reference to the accompanying drawings, in which example embodiments are shown. Example embodiments of the inventive concepts may, however, be embodied in many different forms and should not be construed as being limited to the embodiments set forth herein; rather, these embodiments are provided so that this disclosure will be thorough and complete, and will fully convey the concept of example embodiments to those of ordinary skill in the art. In the drawings, the thicknesses of layers and regions are exaggerated for clarity. Like reference numerals in the drawings denote like elements, and thus their description will be omitted.

It will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout. As used herein the term “and/or” includes any and all combinations of one or more of the associated listed items. Other words used to describe the relationship between elements or layers should be interpreted in a like fashion (e.g., “between” versus “directly between,” “adjacent” versus “directly adjacent,” “on” versus “directly on”).

It will be understood that, although the terms “first”, “second”, etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular embodiments only and is not intended to be limiting of example embodiments. As used herein, the singular forms “a,” “an” and “the” are intended to include the plural forms as well, unless the context clearly indicates otherwise. It will be further understood that the terms “comprises”, “comprising”, “includes” and/or “including,” if used herein, specify the presence of stated features, integers, steps, operations, elements and/or components, but do not preclude the presence or addition of one or more other features, integers, steps, operations, elements, components and/or groups thereof.

Example embodiments of the inventive concepts are described herein with reference to cross-sectional illustrations that are schematic illustrations of idealized embodiments (and intermediate structures) of example embodiments. As such, variations from the shapes of the illustrations as a result, for example, of manufacturing techniques and/or tolerances, are to be expected. Thus, example embodiments of the inventive concepts should not be construed as limited to the particular shapes of regions illustrated herein but are to include deviations in shapes that result, for example, from manufacturing. For example, an implanted region illustrated as a rectangle may have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of example embodiments.

Unless otherwise defined, all terms (including technical and scientific terms) used herein have the same meaning as commonly understood by one of ordinary skill in the art to which example embodiments of the inventive concepts belong. It will be further understood that terms, such as those defined in commonly-used dictionaries, should be interpreted as having a meaning that is consistent with their meaning in the context of the relevant art and will not be interpreted in an idealized or overly formal sense unless expressly so defined herein.

### Embodiments

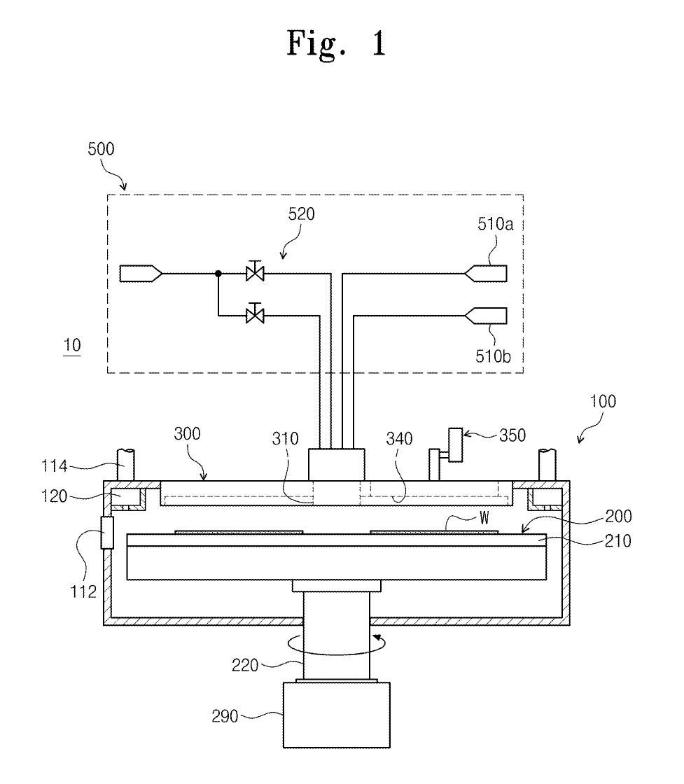

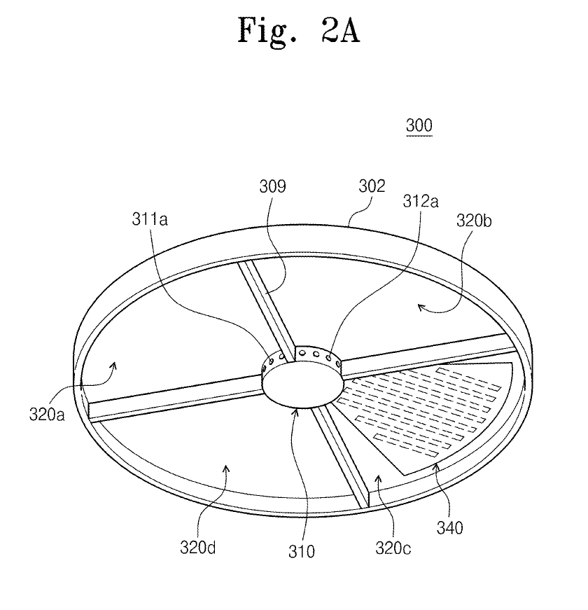

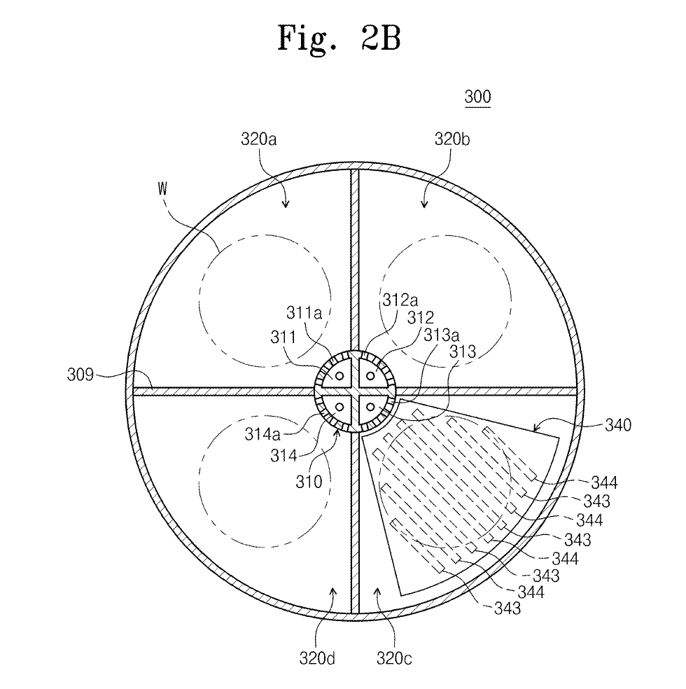

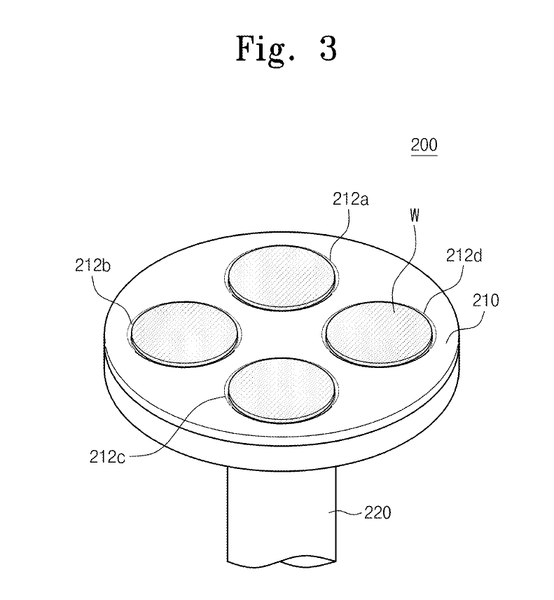

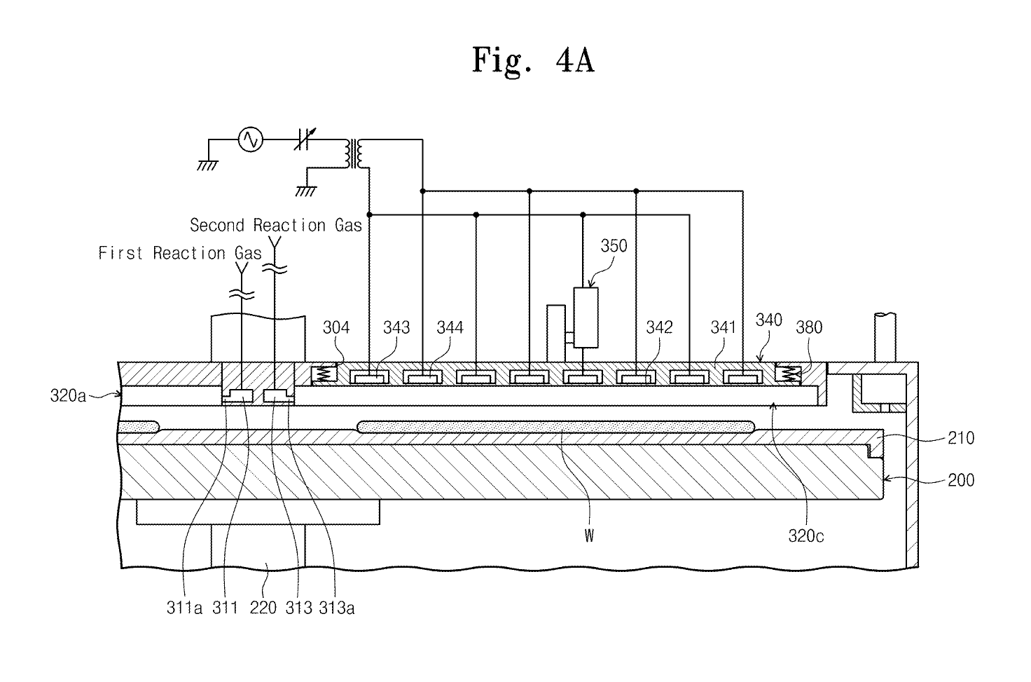

FIG. 1 is a schematic diagram of a deposition apparatus according to example embodiments of inventive concepts, FIGS. 2A and 2B are perspective and sectional views of the injection member of FIG. 1, and FIG. 3 is a plan view of the support member of FIG. 1.

Referring to FIGS. 1 through 3, a deposition apparatus 10 may include a process chamber 100, a support member 200, an injection member 300, and a supplying member 500.

The process chamber 100 may include an entrance 112 provided at one side thereof. During a process, wafers (or substrates) W may be loaded in or unloaded from the process chamber 100 through the entrance 112. The process chamber 100 may include a ventilation duct 120 and a ventilation conduit 114 that are configured to exhaust a reaction gas and a purge gas supplied into the process chamber 100 and by-products of reaction generated during a depositing process. In example embodiments, the ventilation duct 120 and the ventilation conduit 114 may be provided at an upper edge portion of the process chamber 100. the ventilation duct 120 may be shaped like a ring and be positioned outside of the injection member 300. Although not shown in the drawings, it would be apparent to a person skilled in this art that the ventilation conduit 114 may be connected to a vacuum pump, and a pressure control valve and a flow control valve, and so forth may be disposed on the ventilation conduit 114.

As shown in FIGS. 1 and 3, the support member 200 may be provided in the process chamber 100.

The support member 200 may have a batch-type structure, which may be, for example, configured to be able to load four substrates thereon. The support member 200 may include a table 210, which may be shaped like a circular disk and be provided with first to fourth stages 212a-212d, and a support pillar 220 supporting the table 210. Each of the substrates W may be disposed on the first to fourth stages 212a-212d, respectively. The first to fourth stages 212a-212d may be configured to have the same or similar shape, e.g., a circular disk shape, as that of the substrate. The first to fourth stages 212a-212d may be disposed around a center of the support member 200, for example, spaced apart from each other by an equal angle of 90 degrees.

The support member 200 may be configured to be rotated by a driving part 290. The driving part 290 may be configured to include a stepping motor, in which an encoder capable of controlling revolution number and speed of a driving motor is provided, and in this example, one cycle process times of the injection member 300, which includes steps related to a first reaction gas, a purge gas, a second reaction gas, and a purge gas time, may be controlled by the encoder.

Although not shown in the drawings, the support member 200 may include a plurality of lift pins (not shown), each of which may be used to elevate or lower the corresponding one of the wafers on the stages. For example, a vertical position of the wafer W may be changed by vertically moving the lift pin, such that the wafer W can be spaced apart from or mounted on the stage of the support member 200. In addition, each of the stages 212a-212d of the support member 200 may be configured to include a heater (not shown) heating the mounted wafer W. The heater may be configured to heat the wafer W up to a predetermined process temperature.

Referring to FIGS. 1 and 2B, the supplying member 500 may include a first gas supplying member 510a, a second gas supplying member 510b, and a purge gas supplying member 520. the first gas supplying member 510a may be configured to supply a first reaction gas to a first chamber 311 of a nozzle part, and the second gas supplying member 510b may be configured to supply a second reaction gas to a third chamber 313, and the purge gas supplying member 520 may be configured to supply a purge gas to a second and fourth chambers 312 and 314. For example, the first reaction gas and the second reaction gas may contain source materials for a thin film to be formed on the wafer W. In a depositing process, a thin film may be formed on the substrate or the wafer W by chemically reacting a plurality of reaction gases, which are supplied onto a surface of wafer, with each other. Furthermore, in the depositing process, a purge gas may be supplied into the reaction chamber between the process steps of supplying the reaction gases, in order to purge a non-reacting gas remaining within the reaction chamber.

The example embodiments of the inventive concepts may not be limited to the afore described example, in which two different reaction gases are supplied using two gas supplying members, and it would be apparent to a person skilled in this art that three or more reaction gases may be, for example, supplied using a plurality of gas supplying members, if necessary.

Referring to FIGS. 1, 2A and 2B, the injection member 300 may be configured to inject at least one gas onto the four wafers on the support member 200.

The injection member 300 may be configured in such a way that first and second reaction gases and a purge gas can be supplied from the supplying member 500 to the injection member 300. The injection member 300 may include a circular upper plate 302, a nozzle part 310, first to fourth baffles 320a-320d, a plasma generator 340, and a level controller 350.

The nozzle part 310 may be disposed at a center of the upper plate 302. The nozzle part 310 may be configured to inject the first and second reaction gases and the purge gas supplied from the supplying member 500 to the first to fourth baffle 320a-320d, individually. In example embodiments, the nozzle part 310 may include four chambers 311, 312, 313, and 314. The first reaction gas may be provided into the first chamber 311, and injection openings 311a may be formed on a sidewall of the first chamber 311 to supply the first reaction gas into the first baffle 320a. The second reaction gas may be provided into the third chamber 313, and injection openings 313a may be formed on a sidewall of the third chamber 313 to supply the second reaction gas into the third baffle 320c. The purge gas may be supplied into the second and fourth chambers 312 and 314, which may be provided between the first and third chambers 311 and 313. And, injection openings 312a and 314a may be formed on sidewalls of the second and fourth chambers 312 and 314 to supply the purge gas into the second baffle 320b and the fourth baffle 320d.

Each of the first to fourth baffles 320a-320d may include an isolated space for providing the gases, which are supplied from the nozzle part 310, onto the whole surface of the wafer. The first to fourth baffles 320a-320d may be delimited by partitions 309 provided on a bottom surface of the upper plate.

The first to fourth baffles 320a-320d may be radicalized under the upper plate 302, and each of them may have a fan-shaped structure with an angle of 90 degree around the nozzle part 310. The first to fourth baffles 320a-320d may be connected to the injection openings 311a, 312a, 313a, and 314a, respectively, of the nozzle part 310. Each of the first to fourth baffles 320a-320d may have an open-shaped bottom portion facing the support member 200.

The gases provided from the nozzle part 310 may be supplied into the first to fourth baffles 320a-320d, respectively. For example, the gases may be provided onto the wafers W through open-shaped bottom portions of the first to fourth baffles 320a-320d. the first reaction gas may be provided into the first baffle 320a, and the second reaction gas may be provided into the third baffle 320c, and a purge gas may be provided into the second and fourth baffles 320b and 320d, which are located between the first and third baffles 320a and 320c, to prevent the first reaction gas from being mixed with the second reaction gas and to purge a non-reacting gas remaining within the second and fourth baffles 320b and 320d.

In the meantime, the example embodiments of the inventive concepts will not be limited to the example, in which each of the first to fourth baffles 320a-320d have a fan-shape with an angle of 90 degree. For example, the baffles in the injection member 300 may have different angle (e.g., of 45 or 180 degree) and/or different size from that of the afore-described example, if necessary.

According to the example embodiments of the inventive concept, the wafer or the substrate may pass through the spaces provided below the first to fourth baffles 320a-320d, sequentially, due to the rotation of the support member 200. If the wafers W pass through all of the first to fourth baffles 320a-320d, an atomic layer may be deposited on the wafers. Furthermore, by repeating this process, a layer can be formed on the wafers W to have a predetermined thickness.

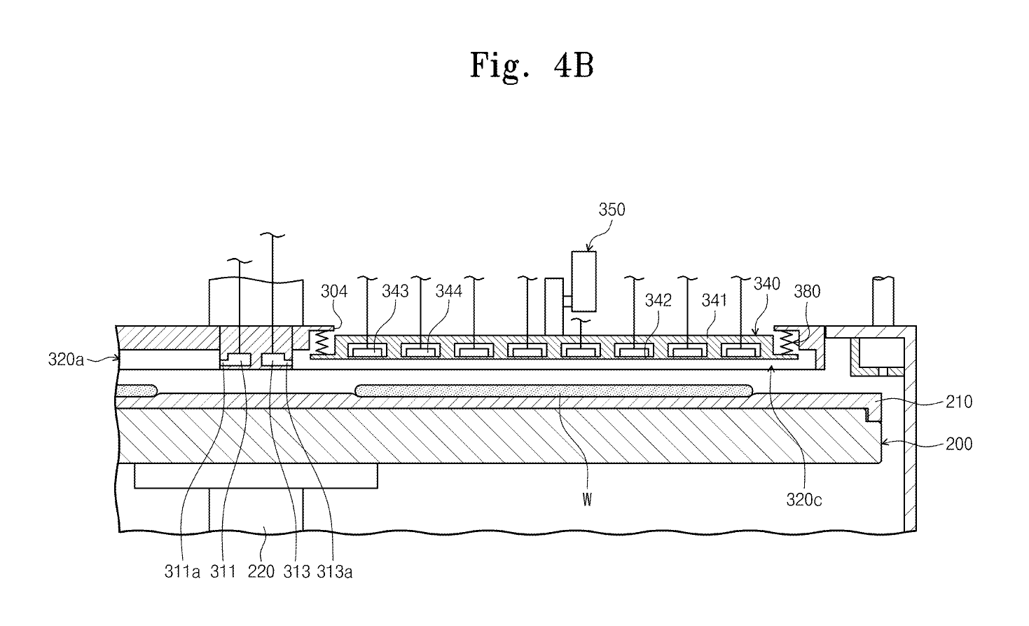

FIG. 4A is a sectional view enlarging the plasma generator of the injection member, and FIG. 4B is a sectional view illustrating a configuration, in which the plasma generator of FIG. 4A is lowered by a level controller.

The plasma generator 340, one of the major parts, may be disposed on at least one baffle of the injection member 300 and be configured to be vertically movable. In example embodiments, the plasma generator 340 may be provided on the third baffle 320c, but example embodiments of the inventive concepts may not be limited thereto. In other words, it is obvious that the plasma generator 340 may be provided on other baffle.

Referring to FIGS. 2A, 2B, 4A and 4B, the plasma generator 340 may be equipped in an opening 304 of the upper plate 302 provided at a region around the third baffle 320c. The plasma generator 340 may be configured to be vertically movable independent of the third baffle 320c. In order to maintain the sealed state, the plasma generator 340 may be surrounded by a bellows 380. Although not shown in the drawings, in the case in which the injection member 300 is provided in the process chamber, the plasma generator 340 may be connected to a separate lifting axis, which may be provided through an upper cover of the process chamber. A portion of the lifting axis, which is positioned outside the process chamber, may be elevated or lowered by the level controller 350. The bellows 380 may be configured to surround the lifting axis penetrating the upper cover of the process chamber. In example embodiments, since the upper plate of injection member constitutes a portion of the upper cover of the process chamber, the bellows 380 may be equipped on the opening 304 to surround the plasma generator 340.

The plasma generator 340 may be disposed on the third baffle 320c to generate plasma from the second reaction gas, and therefore, it is possible to improve reactivity of the second reaction gas and increase a plasma density in the third baffle 320c. This enables to increase a deposition rate and a layer quality of a thin film.

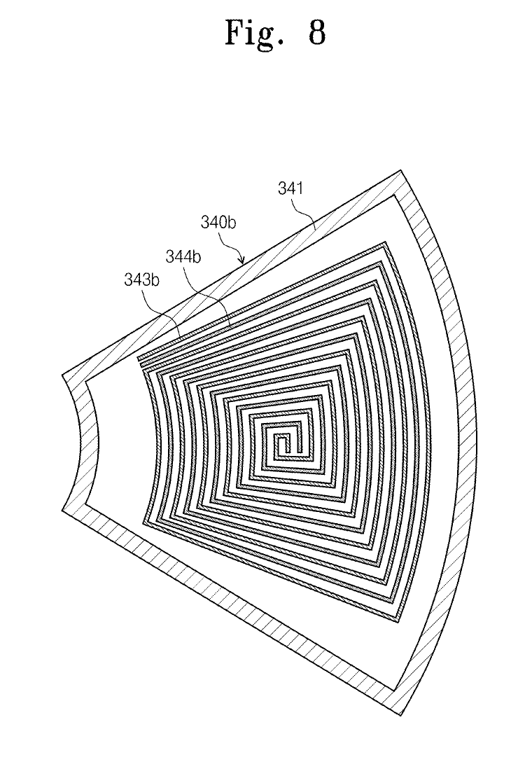

The plasma generator 340 may include first electrodes 343, which may be applied with a high frequency power to generate plasma from a gas, and second electrodes 344, which may be interposed between the first electrodes 343 and be applied with a bias power. The first and second electrodes 343 and 344 may be installed on a bottom surface 342 of a body portion 341 of the plasma generator 340 to be coplanar with each other. The first and second electrodes 343 and 344 may be alternatingly arranged with each other and spaced apart from each other by the same interval, and each of them may have a bar shape. In example embodiments, the first and second electrodes 343 and 344 may be configured to have longitudinal axes substantially crossing a tangential direction of the injection member 300. For example, the first and second electrodes 343 and 344 may be arranged to form a comb-type or radial-type structure. The second electrodes 344 may be applied with another high frequency power. In other example embodiments, as shown in FIG. 8, the first and second electrodes 343 and 344 may be coplanar with each other and be formed to have coil-like structures.

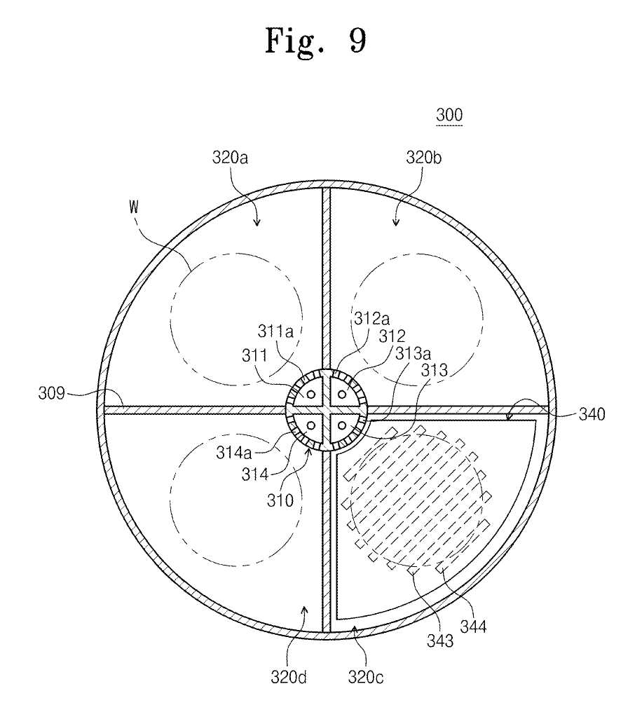

In still other example embodiments, as shown in FIG. 9, the first and second electrodes 343 and 344 may be configured to have longitudinal axes substantially parallel to the tangential direction of the injection member 300. In this case, the first and second electrodes 343 and 344 may be orthogonal to those of FIG. 2.

The bottom surface 342 of the body portion 341 of the plasma generator 340 may be formed to face the support member 200. The body portion 341 of the plasma generator 340 may be formed of insulating, heat-resistive, and chemical-resistive materials (e.g., quartz or ceramics) to prevent the internal environment of the process chamber from being affected by the first and second electrodes 343 and 344.

In example embodiments, a surface of the wafer W may be treated by plasma generated from the second reaction gas, when the wafer W goes through a space below the third baffle 320c provided with the plasma generator 340. For example, if RF and bias powers are applied to the first and second electrodes 343 and 344 of the plasma generator 340 and the second reaction gas is applied to the third baffle 320c through the third chamber 313 of the nozzle part 310, the second reaction gas may be turned into plasma by an induced magnetic field, which may be generated from the plasma generator 340 provided on the third baffle 320c, and then the plasma from the second reaction gas may be supplied onto the surface of the wafer W.

The level controller 350 may be provided outside the process chamber and be configured to be able to control a vertical position of the plasma generator 340. This enables to control a vertical space between the plasma generator 340 and the wafer W. In other words, according to example embodiments of inventive concepts, by virtue of the use of the level controller 350 capable of controlling the vertical position of the plasma generator 340, a space between the wafer and the plasma existing region (e.g., provided by the third baffle) can be controlled in consideration of variable process parameters, such as, a state of wafer, a kind of gas, and/or process environments, during forming a thin film.

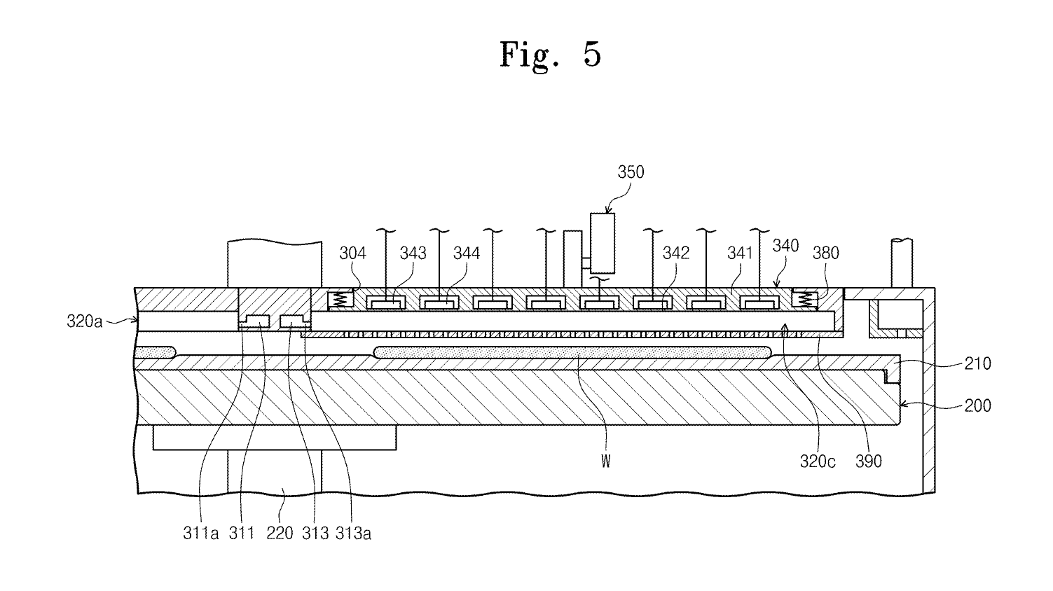

FIG. 5 is a sectional view illustrating a modified example of an injection member, in which a showerhead plate is mounted on a third baffle.

As shown in FIG. 5, the injection member 300 may be configured to have a showerhead plate 390 provided in/on the third baffle 320c. In example embodiments, the showerhead plate 390 may be spaced apart from the plasma generator 340 below the third baffle 320c to face the support member 200. The showerhead plate 390 may include a plurality of injection holes.

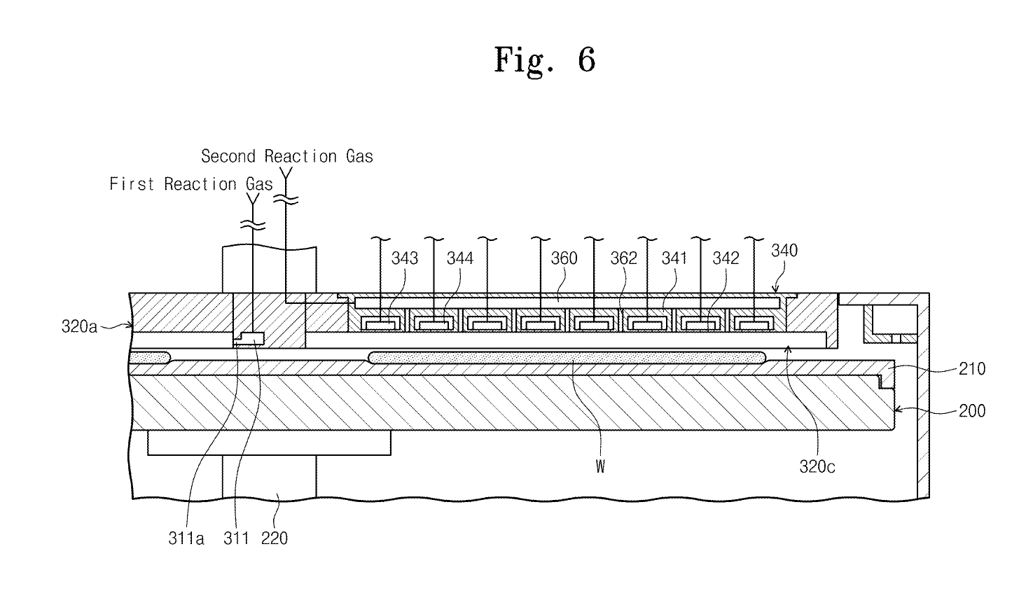

FIG. 6 is a sectional view illustrating an injection member provided with a showerhead-type plasma generator.

As shown in FIG. 6, the plasma generator 340 may be a showerhead-type structure.

For example, the plasma generator 340 may include a buffer space 360, to which a second reaction gas will be supplied, and injections holes 362 disposed between the electrodes 343 and 344 to connect the buffer space 360 with the third baffle 320c. In the injection member depicted by FIG. 6, the second reaction gas may be supplied into the buffer space 360 and then be supplied into the third baffle 320c through the injection holes 362.

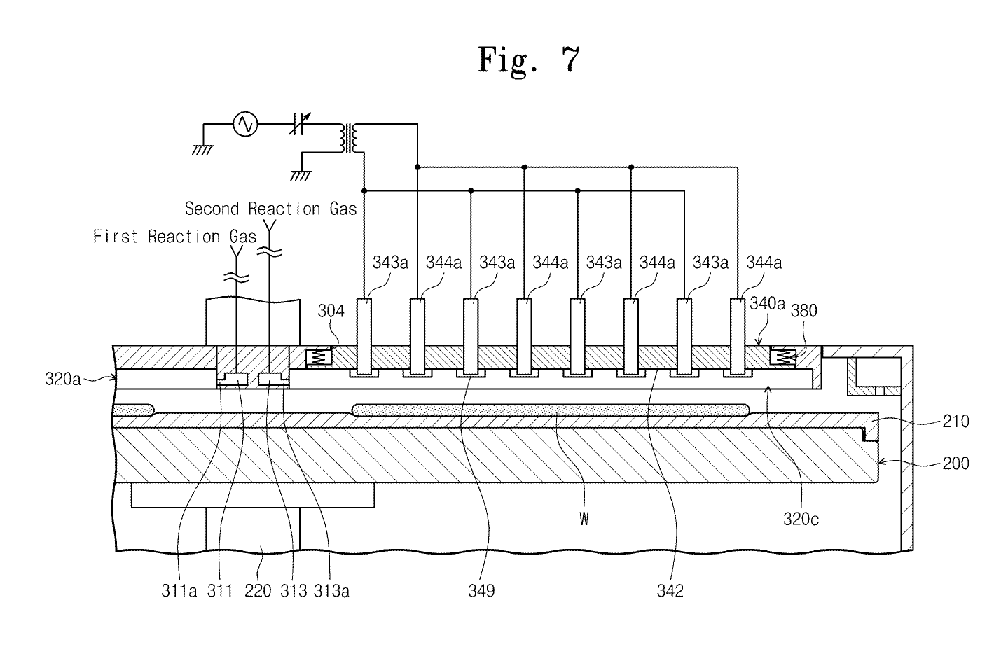

FIG. 7 is a sectional view illustrating an example of an injection member, in which first and second electrodes are equipped on a bottom surface of a plasma generator in order to improve accessibility to the substrate. In order to reduce complexity in the drawings and to provide better understanding of example embodiments of the inventive concepts, the level controller is not shown in FIG. 7.

As shown in FIG. 7, the first electrodes 343a and the second electrodes 344a may be provided to penetrate the bottom surface 342 of the plasma generator 340a, and extensions of the first electrodes 343a and the second electrodes 344a protruding from the bottom surface 342 may be covered with an insulating material 349.

For the deposition apparatus according to the example embodiments of the inventive concepts, the plasma generator may be equipped to the injection member in a semi-remote plasma manner, and thus, a thin-film forming process including directly decomposing the reaction gas into radicals can be performed under the condition, in which a distance between the plasma generator and the wafer is in a range of from several millimeters to several centimeters. The plasma generator may generate plasma by simultaneously using both of the first electrode and the second electrode, and thus, there is no necessity for providing additional parts to the process chamber.

For a conventional single apparatus, a susceptor is vertically moved to control a space between the plasma existing region and the wafer. By contrast, for the batch-type structure exemplified by the afore-described embodiments of the inventive concept, the plasma generator is vertically moved to control a space between the wafer and the plasma generator during formation of a thin film, in consideration of variable process parameters, such as, a state of wafer, a kind of gas, and/or process environments.

The inventive concept may be applied to apparatuses configured to inject successively at least two different gases onto wafers or substrates, in order to treat surfaces of wafers or substrates with plasma. Although batch-type deposition apparatuses have been described as examples of the inventive concepts, but example embodiments of the inventive concepts may not be limited thereto. For example, the inventive concept can be applied to realize a deposition apparatus using high density plasma (HDP) or any deposition or etching apparatus using plasma.

According to example embodiments of inventive concepts, a vertical position of a plasma generator is configured to be controllable. This enables to adjust a space between the plasma generator and a substrate selectively.

In addition, the plasma generator may be provided on a baffle to turn a reaction gas into plasma, and thus, it is possible to improve reactivity of the reaction gas, increase a plasma density in the baffle. This enables to increase a deposition rate and a layer quality of a thin film.

Furthermore, according to example embodiments of inventive concepts, at least two different gases can be injected onto the substrate or the wafer, and thus, it is possible to increase efficiency of a depositing process or a surface treatment. This enables to increase the number of substrates or wafers to be treated in unit time, with high reliability, and to improve a yield or productivity in the fabrication of semiconductor devices.

While example embodiments of the inventive concepts have been particularly shown and described, it will be understood by one of ordinary skill in the art that variations in form and detail may be made therein without departing from the spirit and scope of the attached claims.

1. A plasma processing apparatus, comprising:
a process chamber configured to perform a plasma using process and contain a plurality of substrates;
a support member provided in the process chamber, the substrates being laid on the same level of the support member;
an injection member provided to face the support member and include a plurality of baffles, such that at least one reaction gas and a purge gas can be injected onto the substrates in an independent manner; and
a driving part configured to rotate the support member or the injection member, such that the baffles of the injection member can orbit with respect to the plurality of the substrates laid on the support member,
wherein the injection member comprises a plasma generator, which is provided on at least one, configured to inject the reaction gas, of the baffles to turn the reaction gas into plasma.

2. The apparatus of claim 1, wherein the injection member further comprises a level controller configured to be able to control a vertical position of the plasma generator, thereby adjusting a space between the plasma generator and the substrate selectively.

3. The apparatus of claim 1, wherein the injection member is configured to have an opening for equipping the plasma generator to the at least one baffle, and the injection member further comprises a bellows surrounding the plasma generator to maintain a sealed state.

4. The apparatus of claim 1, wherein the plasma generator comprises:
a body portion having a bottom surface facing the substrate;
first electrodes provided on the bottom surface of the body portion and applied with a high frequency power for turning a gas into plasma; and
second electrodes provided on the bottom surface of the body portion and between the first electrodes and applied with a bias power.

5. The apparatus of claim 4, wherein the first electrodes and the second electrodes are coplanar with each other and form a radial configuration, thereby allowing the substrate to be uniformly exposed by a plasma existing region during a rotation of the support member or the injection member.

6. The apparatus of claim 4, wherein the first electrodes and the second electrodes are arranged to form a comb-type configuration.

7. The apparatus of claim 1, wherein the plasma generator comprises:
a body portion having a bottom surface facing the substrate;
first electrodes provided on the bottom surface of the body portion and applied with a high frequency power for turning a gas into plasma; and
second electrodes provided on the bottom surface of the body portion and between the first electrodes and applied with a bias power,
wherein the first electrodes and the second electrodes are arranged at the same level to form coil-like configurations.

8. The apparatus of claim 1, wherein the injection member comprises:
an upper plate shaped like a circular disk; and
partitions provided on a bottom surface of the upper plate to delimit the baffles.

9. The apparatus of claim 8, wherein the injection member further comprises a nozzle part provided at a center of the upper plate and configured to inject each of the at least one reaction gas and the purge gas into the corresponding one of the baffles.

10. The apparatus of claim 1, wherein the injection member further comprises a showerhead plate provided to face the support member, and the showerhead plate is equipped below the baffle provided with the plasma generator and is spaced apart from the plasma generator.

11. An injection member for a plasma processing apparatus, comprising:
an upper plate shaped like a circular disk; and
a nozzle part provided at a center of the upper plate to have at least four injection openings, each of which is configured to inject the corresponding one of reaction and purge gases in an independent manner;
at least four baffles provided on the upper plate to form a radial configuration around the nozzle part, each of the at least four baffles being connected to the corresponding one of the at least four injection openings to contain the corresponding one of the gases separately; and
a plasma generator provided on one of the at least four baffles to turn the reaction gas into plasma.

12. The injection member of claim 11, wherein the injection member further comprises a level controller configured to control a vertical position of the plasma generator.

13. The injection member of claim 11, wherein the injection member is configured to have an opening for equipping the plasma generator to the baffle, and the injection member further comprises a bellows surrounding the plasma generator to maintain a sealed state.
